(19) United States
(12) Patent Application Publication
(10) Pub. No.: US 2025/0014902 A1
(43) Pub. Date: Jan. 9, 2025

(54) METHOD OF MANUFACTURING A SEMICONDUCTOR DEVICE INCLUDING ION IMPLANTATION PROCESSES

(71) Applicant: Infineon Technologies AG, Neubiberg (DE)

(72) Inventors: Axel König, Villach (AT); Kristijan Luka Mletschnig, Klagenfurt (AT); Andreas Vörckel, Finkenstein (AT); Caspar Leendertz, München (DE); Werner Schustereder, Villach (AT); Hans-Joachim Schulze, Taufkirchen (DE)

(21) Appl. No.: 18/754,277

(22) Filed: Jun. 26, 2024

(30) Foreign Application Priority Data
Jul. 4, 2023 (DE) 102023117657.9

(51) Int. Cl. H01L 21/04; H01L 21/02; H01L 21/324

(52) U.S. Cl. CPC H01L 21/0465; H01L 21/02378; H01L 21/02576; H01L 21/02579; H01L 21/324

(57) ABSTRACT

A method of manufacturing a semiconductor device includes forming a doped region in a semiconductor body. Forming the doped region includes: introducing first dopants through a first surface of the semiconductor body at a first vertical reference level by a first ion implantation process; thereafter, applying a first heat treatment to the semiconductor body; and thereafter, introducing second dopants through the first surface of the semiconductor body at the first vertical reference level by a second ion implantation process. An atomic number of the first dopants is equal to an atomic number of the second dopants. An ion implantation energy of the second ion implantation process differs by less than 20% from an ion implantation energy of the first ion implantation process. An ion implantation dose of the second ion implantation process differs by less than 20% from an ion implantation dose of the first ion implantation process.

### TECHNICAL FIELD

The present disclosure is related to a method of manufacturing a semiconductor device, in particular to a method including forming a doped region in a semiconductor body by ion implantation processes.

### BACKGROUND

Technology development of new generations of power semiconductor devices, e.g. insulated gate field effect transistors (IGFETs) such as metal oxide semiconductor field effect transistors (MOSFETs) or insulated gate bipolar transistors (IGBTs) or junction field effect transistors (JFETs) or freewheeling diodes, aims at improving electric device characteristics, e.g. area-specific on-state resistance. By tailoring the characteristics of doped semiconductor regions, e.g. peaks, slopes, extensions, electric device parameters may be adapted to the specific needs of the semiconductor device.

There is a steady need for improving flexibility of forming doped semiconductor regions.

### SUMMARY

An example of the present disclosure relates to a method of manufacturing a semiconductor device. The method includes forming a doped region in a semiconductor body. Forming the doped region includes introducing first dopants through a first surface of the semiconductor body at a first vertical reference level by a first ion implantation process. Thereafter a first heat treatment is applied to the semiconductor body. Thereafter, second dopants are introduced through the first surface of the semiconductor body at the first vertical reference level by a second ion implantation process. An atomic number of the first dopants is equal to an atomic number of the second dopants. An ion implantation energy of the second ion implantation process differs by less than 20% from an ion implantation energy of the first ion implantation process. An ion implantation dose of the second ion implantation process differs by less than 20% from an ion implantation dose of the first ion implantation process.

Another example of the present disclosure relates to a further method of manufacturing a semiconductor device. The method includes forming a doped region in a semiconductor body. Forming the doped region includes introducing first dopants through a first surface of the semiconductor body at a first vertical reference level by a first ion implantation process. The first dopants are implanted along a beam axis that deviates by at most 1.5° from a main crystal axis of the semiconductor body along which channeling occurs. Thereafter, a first heat treatment is applied to the semiconductor body. Thereafter, second dopants are introduced through the first surface of the semiconductor body at the first vertical reference level by a second ion implantation process. The second dopants are implanted along a beam axis that deviates by at most 1.5° from a main crystal axis of the semiconductor body along which channeling occurs.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor device processing features and together with the description serve to explain principles of the examples. Further examples are described in the following detailed description and the claims.

FIGS. 1A to 1C are schematic cross-sectional views for illustrating process features of a method for manufacturing a semiconductor device including forming a doped region.

FIG. 2 is a schematic cross-sectional view for illustrating a process feature of electrically activating dopants of the doped region.

FIGS. 3A to 3C are schematic cross-sectional views for illustrating further process features of a method for manufacturing a semiconductor device including forming a doped region.

FIGS. 4 and 5 are schematic cross-sectional views for illustrating configuration examples of a semiconductor device including a doped region formed by the process features described with reference to FIGS. 1A to 1C.

FIG. 6 is a schematic illustration of simulated channeling profiles.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B, as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate

An example of a method of manufacturing a semiconductor device includes forming a doped region in a semiconductor body. Forming the doped region may include introducing first dopants through a first surface of the semiconductor body at a first vertical reference level by a first ion implantation process. Thereafter, a first heat treatment may be applied to the semiconductor body. Thereafter, second dopants may be introduced through the first surface of the semiconductor body at the first vertical reference level by a second ion implantation process. An atomic number of the first dopants may be equal to an atomic number of the second dopants. An ion implantation energy of the second ion implantation process may differ by less than 20%, or by less than 10%, or even by less than 5%, from an ion implantation energy of the first ion implantation process. An ion implantation dose of the second ion implantation process may differ by less than 20%, or by less than 10%, or even by less than 5%, from an ion implantation dose of the first ion implantation process.

The semiconductor body may have a crystal lattice suitable for channeling ions. Typically, in some crystal directions of single-crystalline materials open spaces extend straight into the crystal. The open spaces form channels through which ions travel with less interaction with the atoms of the crystal lattice than outside the channels. The channels govern the motion of the ions, wherein the ions entering such channels show a deceleration pattern that differs from the deceleration pattern for ions entering the semiconductor body outside the channels. In other words, in some crystal directions of single-crystalline materials the atoms align in such a way that they are forming so called channels in which the incoming ion flux is restricted. The channel directions coincide with main crystal directions.

The first and second dopants may be implanted into the semiconductor body via ions of the respective element or element compound, for example. For example, no other ion implantations may be carried out between the ion implantation of the first dopants and the ion implantation of the second dopants, for example. In addition to the first and second ion implantation processes, further ion implantation processes may be carried out for forming the doped region. For example, each of the further ion implantation processes in addition to the first and second ion implantation processes may be carried out either before the first ion implantation process or after the second ion implantation process. A further heat treatment may be carried out after each or some of the additional ion implantation processes. A sequence of n ion implantations followed by crystal damage annealing may be carried out for forming the doped region, n being an integer equal to or larger than 2, e.g. 3, 4, 5, 6, 7, 8, 9, 10, or even larger. For example, between ion implantation processes, a semiconductor layer may be formed on a surface of the semiconductor body from where dopants enter the semiconductor body by the ion implantation processes. This may allow for enlarging a vertical extent of the doped region. Parameters of the additional ion implantation processes, e.g. ion implantation energy, and/or ion implantation dose, and/or ion implantation tilt angle with respect to the vertical axis on the first surface may be similar to the first and/or second ion implantation process.

The first vertical reference level is measured relative to a fixed vertical position inside the semiconductor body and may define an outer surface of the semiconductor body. When a semiconductor layer is deposited on the first surface at the first reference level by a semiconductor layer deposition process followed by a subsequent ion implantation process into the deposited semiconductor layer, the subsequent ion implantation process will introduce dopants through a surface of the deposited semiconductor layer that is located at a second vertical reference level different from the first vertical reference level. While the first vertical reference level may define the outer surface of the semiconductor layer before the layer deposition process, the second vertical reference level may define the outer surface of the semiconductor body plus the deposited semiconductor layer.

The first heat treatment may be carried out for annealing the semiconductor body. The first heat treatment may be carried out by a furnace process or by rapid thermal processing, RTP. In addition or as an alternative, annealing may be carried out by melt or non-melt laser thermal annealing, LTA. This may allow for reducing or minimizing crystal damage in the irradiated zone by a suitable annealing budget. Thereby, channeling performance degradation or de-channeling of subsequent ion implantation of dopants, e.g. the second ion implantation process, due to crystal damage by the first ion implantation process may be reduced or minimized. This may allow for an improvement in tuning a vertical dopant concentration profile, for example.

The semiconductor device may be an integrated circuit, or a discrete semiconductor device or a semiconductor module, for example. The semiconductor device may be or include a power semiconductor device, e.g. a vertical power semiconductor device having a load current flow between a first surface and a second surface. The semiconductor device may be or may include a power semiconductor IGFET, e.g. a power semiconductor MOSFET, or a power semiconductor IGBT. The power semiconductor device may be configured to conduct currents of more than 1 A or more than 10 A or even more than 30 A, and may be further configured to block voltages between load electrodes, e.g. between emitter and collector of an IGBT, or between drain and source of a MOSFET in the range of several hundreds of up to several thousands of volts, e.g. 400 V, 650V, 1.2 kV, 1.7 kV, 3.3 kV, 4.5 kV, 5.5 kV, 6 kV, 6.5 kV. The blocking voltage may correspond to a voltage class specified in a datasheet of the power semiconductor device, for example.

For example, the semiconductor body may be or may include a crystalline SiC semiconductor substrate. For example, the crystalline SiC semiconductor substrate may have a hexagonal polytype, e.g., 4H or 6H. The semiconductor body may be homogeneously doped or may include differently doped SiC layer portions, e.g., with a doping concentration of at least 2×10¹⁷ cm⁻³ and at most 1×10¹⁹ cm⁻³, for example of at least 5×10¹⁷ cm⁻³ and at most 1×10¹⁹ cm⁻³ or may be nominally undoped (e.g., with a doping concentration of at most 1×10¹⁷ cm⁻³ or of at most 1×10¹⁵ cm⁻³; so-called “not intentionally doped silicon carbide”). For example, the semiconductor body may include, e.g. as differently doped SiC layer portions, a substantially homogeneously doped SiC semiconductor substrate and an epitaxial buffer layer on the SiC semiconductor substrate. For example, the semiconductor body may include one or more layers from another material with a melting point close to or higher than crystalline silicon carbide. For example, the layers from another material may be embedded in the crystalline SiC semiconductor substrate. The crystalline SiC semiconductor substrate may have two essentially parallel main surfaces of the same shape and size and a lateral surface area connecting the edges of the two main surfaces. For example, the silicon carbide semiconductor substrate may be a rectangular prism with or without rounded edges or a right cylinder or a slightly oblique cylinder (e.g. where the sides lean with an angle of at most 8° or at most 5° or at most 3°) with or without one or more flats or notches along the outer circumference. As an alternative to SiC, a wide band gap semiconductor wafer may be processed, e.g. comprising a wide band gap semiconductor material different from silicon carbide. The wide band gap semiconductor wafer may have a band gap larger than the band gap of silicon (1.1 eV). For example, the wide band gap semiconductor wafer may be a gallium arsenide (GaAs) wafer, or a gallium nitride (GaN) wafer. As an alternative to SiC and wide band gap materials, also a silicon semiconductor body may be used. For example, the semiconductor body may have a diamond cubic crystal lattice like silicon (Si). In case of a diamond cubic crystal lattice, a surface of the semiconductor body may coincide with a (100) crystal face, may be tilted to the {100} crystal face by at most ±2 degree or may be any other face suitable for channeling. Accordingly, a <100> crystal direction, which is one of several main crystal directions along which channeling occurs, or any other suitable direction, runs perpendicular to the process surface.

By dividing an ion implantation dose of an ion implantation process into a plurality of ion implantations having a lower dose with intermediate heat treatments for annealing crystal damage caused by the previous implantation, a resulting ion implantation profile of the plurality of ion implantations may allow for a larger flexibility in profile shaping compared with a single ion implantation process or less ion implantation processes having a same total dose as the plurality of ion implantations. The intermediate heat treatments for annealing the crystal damage of the previous ion implantation process improve channeling ion implantations of subsequent ion implantations by reducing de-channeling or channeling degradation effects. More specifically, the concentration of implanted ions in the channeling tail region can be increased as a consequence of the reduced crystal damage by applying intermediate heat treatments.

For example, the first and/or second dopants may be implanted along a beam axis that deviates by at most 1.5°, or by at most 1.0°, or by at most 0.5°, or by at most 0.3°, or by at most 0.1° from a main crystal axis of the semiconductor body along which channeling occurs. For example, a maximum tilt angle between a main beam direction and the main crystal direction along which channeling of ions occurs as well as an implant beam incidence angle variability of at most ±0.5 degree may be valid for at least 80% of the surface of the semiconductor body.

Details with respect to process features described above likewise apply to a further example of a method of manufacturing a semiconductor device. The method includes forming a doped region in a semiconductor body. Forming the doped region may include introducing first dopants through a first surface of the semiconductor body at a first vertical reference level by a first ion implantation process. The first dopants may be implanted along a beam axis that deviates by at most 1.5° from a main crystal axis of the semiconductor body along which channeling occurs. Thereafter, a first heat treatment may be applied to the semiconductor body. Thereafter, second dopants through the first surface of the semiconductor body at the first vertical reference level by a second ion implantation process. The second dopants may be implanted along a beam axis that deviates by at most 1.5° from a main crystal axis of the semiconductor body along which channeling occurs. For example, the semiconductor body may be a SiC semiconductor body and the main crystal axis is the c-axis. For example, an atomic number of the first dopants may be different to an atomic number of the second dopants. In addition or as an alternative, an ion implantation energy of the second ion implantation process may differ by less than 20%, or by less than 10%, or even by less than 5%, from an ion implantation energy of the first ion implantation process. In addition or as an alternative, an ion implantation dose of the second ion implantation process may differ by less than 20% from an ion implantation dose of the first ion implantation process.

For example, the second ion implantation energy may be smaller than the first ion implantation energy.

For example, the second ion implantation dose may be smaller than the first ion implantation dose.

For example, an ion implantation mask of the first ion implantation process may be reused for the second ion implantation process.

For example, the method may further include applying an activation heat treatment to the semiconductor body after the second ion implantation process. The activation heat treatment may be configured to electrically activate the first and second dopants. A maximum temperature of the activation heat treatment may be larger than a maximum temperature of the first heat treatment.

The maximum temperature of the activation heat treatment may be larger by more than 400 K, or more than 500 K, or even more than 600 K than the maximum temperature of the first heat treatment. For example, temperature values of the first heat treatment may be in a range from 600° C. to 1000° C., and temperature values of the activation heat treatment may be in a range from 1600° C. to 1900° C.

For example, the maximum temperature of the first heat treatment may configured to anneal crystal damage by the first ion implantation process.

For example, the semiconductor body may be a SiC semiconductor body. The maximum temperature of the first heat treatment may have a value from 600° C. to 1200° C., or from 600° C. to 1000° C., or from 700° C. to 900° C., for example.

For example, the method may further include ion implantation processes in addition to the first and second ion implantation processes. Each of the ion implantation processes in addition to the first and second ion implantation processes may be carried out either before the first ion implantation process or after the second ion implantation process. Between subsequent ion implantation processes including at least one of the additional ion implantation processes, heat treatments for annealing crystal damage may be carried out. An atomic number of the dopants used for the additional ion implantation processed for forming the doped region may be equal to or differ from the atomic number of the first/second dopants, for example.

For example, the doped region may be a p-doped region or an n-doped region of a super junction structure comprising the p-doped region laterally adjoining the n-doped region.

For example, forming the super junction structure may further include forming a semiconductor layer on the first surface of the semiconductor body. Forming the super junction structure may further include introducing third dopants through a surface of the semiconductor layer at a second vertical reference level by a third ion implantation process. Thereafter a second heat treatment may be applied to the semiconductor body and the semiconductor layer. Thereafter, fourth dopants may be implanted through the surface of the semiconductor layer at the second vertical reference level by a fourth ion implantation process. An atomic number of the third dopants may be equal to an atomic number of the fourth dopants. An ion implantation energy of the fourth ion implantation process may differ by less than 20%, or by less than 10%, or even by less than 5%, from an ion implantation energy of the third ion implantation process. An ion implantation dose of the fourth ion implantation process may differ by less than 20%, or by less than 10%, or even by less than 5%, from an ion implantation dose of the third ion implantation process.

For example, forming the super junction structure may further comprise forming a semiconductor layer on the first surface of the semiconductor body. Forming the super junction structure may further include introducing third dopants through a surface of the semiconductor layer at a second vertical reference level by a third ion implantation process and introducing fourth dopants through the surface of the semiconductor layer at the second vertical reference level by a fourth ion implantation process. The introducing of both the first dopants and the third dopants may be conducted prior to the first heat treatment and the introducing of both the second dopants and the fourth dopants may be conducted after the first heat treatment. For example, an atomic number of the third dopants equals an atomic number of the fourth dopants and/or an ion implantation energy of the fourth ion implantation process differs by less than 20% from an ion implantation energy of the third ion implantation process and/or an ion implantation dose of the fourth ion implantation process differs by less than 20% from an ion implantation dose of the third ion implantation process.

For example, both the first dopants and the second dopants form the n-doped region or column of the super junction structure and both the third dopants and the fourth dopants form the p-doped region or column of the super junction structure. In other words, the n-doped and the p-doped regions of the super junction structure may be formed in at least two implantations steps along the channeling axis each. Between the implantation steps, a respective heat treatment may be carried out to heal the crystal lattice to improve channeling in the following implantation step.

For example, the doped region may be an n-doped current spread region of a power semiconductor device including gate trenches. The current spread region may adjoin to a bottom side of the gate trenches. The current spread region may further adjoin to a channel end opposite to another channel end adjoining the source region.

For example, each one of the ion implantation energy of the first ion implantation process and the ion implantation energy of the second ion implantation process may be larger than 1000 keV.

For example, a temperature of the semiconductor body during the introducing of the first dopants is smaller than the temperature of the semiconductor body during the introducing of the second dopants. For example, the second dopants are implanted at a higher temperature of the semiconductor body than the first dopants. For example, the temperature of the semiconductor body differs by at least 10K or even at least 30K. The semiconductor body may be cooled prior to the introducing of the first dopants and/or the semiconductor body may be heated prior to the introducing of the second dopants. This may reduce an influence of phonons and/or an amorphization limit of the semiconductor material of the semiconductor body.

For example, a semiconductor device may include a doped region formed by the method of any one of the examples disclosed herein. The semiconductor device may be a vertical power semiconductor device that may be part of or may be at least one of: an integrated circuit, a discrete semiconductor device, or a semiconductor module, for example. The semiconductor device may be used in applications related to power transmission and distribution, automotive and transport, renewable energy, consumer electronics, and other industrial applications. The vertical power semiconductor device may be or a may include an insulated gate field effect transistor (IGFET) such as a metal oxide semiconductor field effect transistor (MOSFET), an insulated gate bipolar transistor (IGBT), or a junction field effect transistor (JFET), for example. For example, for semiconductor devices based on substrate materials allowing for only low diffusion of dopants, e.g. SiC, the examples described herein may allow for more flexibility in shaping doping concentration profiles. For example, higher concentrations in great depths and box-like profiles may be achieved in such substrate materials. For example, doped regions requiring larger depths for meeting their intended purpose may benefit from the examples disclosed herein. For example, the doped region may be an n-doped current spread region of an n-channel MOSFET. The doped region may also be part, e.g. as an n-doped or p-doped part in the shape of a column, of a super junction, SJ, structure of a super junction MOSFET, for example.

More details and aspects are mentioned in connection with the examples described above or below. Processing the semiconductor body may comprise one or more optional additional features corresponding to one or more aspects mentioned in connection with the proposed concept or one or more examples described above or below.

The aspects and features mentioned and described together with one or more of the previously described examples and figures may as well be combined with one or more of the other examples in order to replace a like feature of the other example or in order to additionally introduce the feature to the other example.

It will be appreciated that while the method is described above and below as a series of steps or events, the described ordering of such steps or events are not to be interpreted in a limiting sense. Rather, some steps may occur in different orders and/or concurrently with other steps or events apart from those described above and below.

Functional and structural details described with respect to the examples above shall likewise apply to the examples illustrated in the figures and described further below.

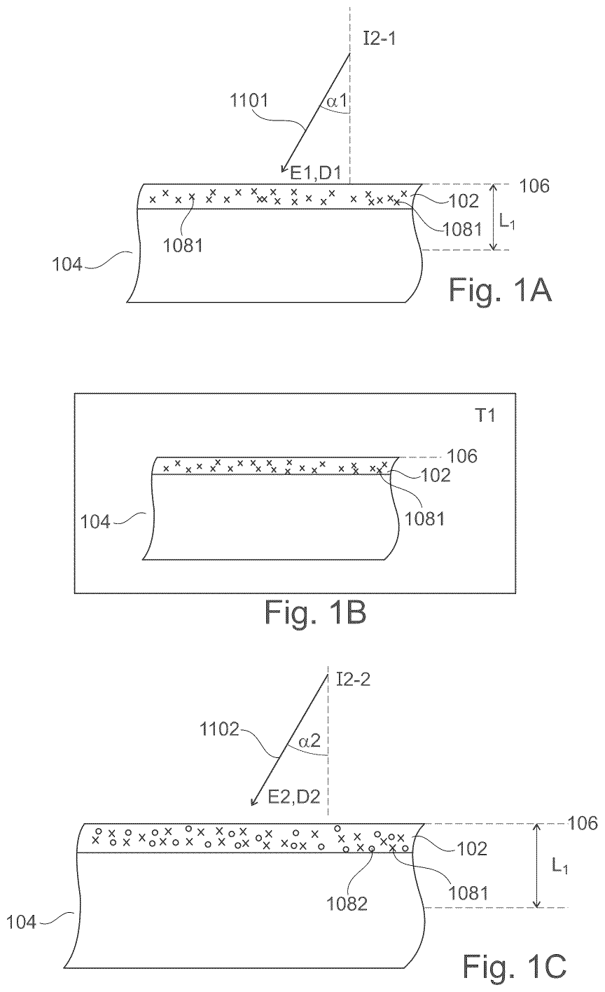

Referring to the schematic cross-sectional views of FIGS. 1A to 1C, exemplary process features for manufacturing a semiconductor device are illustrated.

The illustrated process features of the method illustrate exemplary process features for forming a doped region 102 in a semiconductor body 104.

Referring to FIG. 1A, first dopants 1081 are introduced through a first surface 106 of the semiconductor body 104 at a first vertical reference level L1 by a first ion implantation process I2-1. The first vertical reference level L1 refers to a predetermined vertical position inside the semiconductor body 104. The first dopants 1081 are implanted along a beam axis 1101 having angle α1 with respect to a vertical axis on the first surface 106. For example, the angle α1 may deviate by at most 1.5° from a main crystal axis of the semiconductor body 104 along which channeling occurs, e.g. the c-axis in a SiC semiconductor body. The first ion implantation process I2-1 is based on an ion implantation energy E1 and an ion implantation dose D1.

Referring to FIG. 1B, a first heat treatment T1 is applied to the semiconductor body 104. For example, the first heat treatment T1 may include annealing the semiconductor body 104 by a furnace process or rapid thermal processing, RTP. In addition or as an alternative, annealing may be carried out by melt or non-melt laser thermal annealing, LTA. This may allow for reducing or minimizing crystal damage in the irradiated zone by a suitable annealing.

Referring to FIG. 1C, after the first heat treatment T1, second dopants 1082 are introduced through the first surface 106 of the semiconductor body 104 at the first vertical reference level L1 by a second ion implantation process I2-2. The second dopants 1082 are implanted along a beam axis 1102 having angle α2 with respect to the vertical axis on the first surface 106. For example, the angle α2 may deviate by at most 1.5° from a main crystal axis of the semiconductor body 104 along which channeling occurs, e.g. the c-axis in a SiC semiconductor body. The second ion implantation process I2-2 is based on an ion implantation energy E2 and an ion implantation dose D2. An atomic number of the first dopants 1081 is equal to an atomic number of the second dopants 1082. For example, the first and second dopants may be Al for p-type doping, e.g. in a semiconductor body made of SiC or Si. For example, the first and second dopants may be P for n-type doping, e.g. in a semiconductor body made of SiC or Si. The ion implantation energy E2 of the second ion implantation process I2-2 differs by less than 20%, or by less than 10%, or by less than 5%, from the ion implantation energy E1 of the first ion implantation process I2-1. The ion implantation dose D2 of the second ion implantation process I2-2 differs by less than 20%, or by less than 10%, or by less than 5%, from the ion implantation dose D1 of the first ion implantation process I2-1.

Further process features may be carried out, e.g. before, after, or between the process features illustrated with respect to FIGS. 1A, 1B, 1C. Examples of further process feature are, inter alia, deposition processes for forming insulating layers, or semiconductor layers or conducting layers, etching processes, e.g. via lithographic etch mask(s), for patterning structures, and doping processes for forming further doped regions in the semiconductor body 104. Exemplary doped regions include source and drain regions or emitter and collector regions, body region(s), body contact region(s), current spread region(s), shielding region(s) configured to shield a gate dielectric from high electric fields, field stop region(s). Exemplary insulating layers include gate dielectric(s), interlayer insulating dielectric(s) in a wiring area above the semiconductor body 104. Exemplary semiconducting layers include gate electrode(s), field electrode(s), floating electrode(s) formed by highly doped semiconductor materials. Exemplary conducting layers include patterned wiring level(s), e.g. patterned metal wiring layer(s), vias, contact plugs, bond pad(s).

In the example illustrated in FIGS. 1A to 1C, formation of the doped region 102 has been illustrated based on two ion implantation processes I2-1, I2-2. The two ion implantation processes I2-1, I2-2 for forming the doped region 102 are only exemplary and by no way limiting. Further ion implantation processes in addition to the first and second ion implantation processes I2-1, I2-2 may be carried out for forming the doped region 102. For example, each of the ion implantation processes in addition to the first and second ion implantation processes I2-1, I2-2 may be carried out either before the first ion implantation process I2-1 or after the second ion implantation process I2-2. Parameters of the additional ion implantation processes, e.g. ion implantation energy, and/or ion implantation dose, and/or ion implantation tilt angle with respect to the vertical axis on the first surface 106, may be similar to the first and/or second ion implantation process I2-1, I2-2.

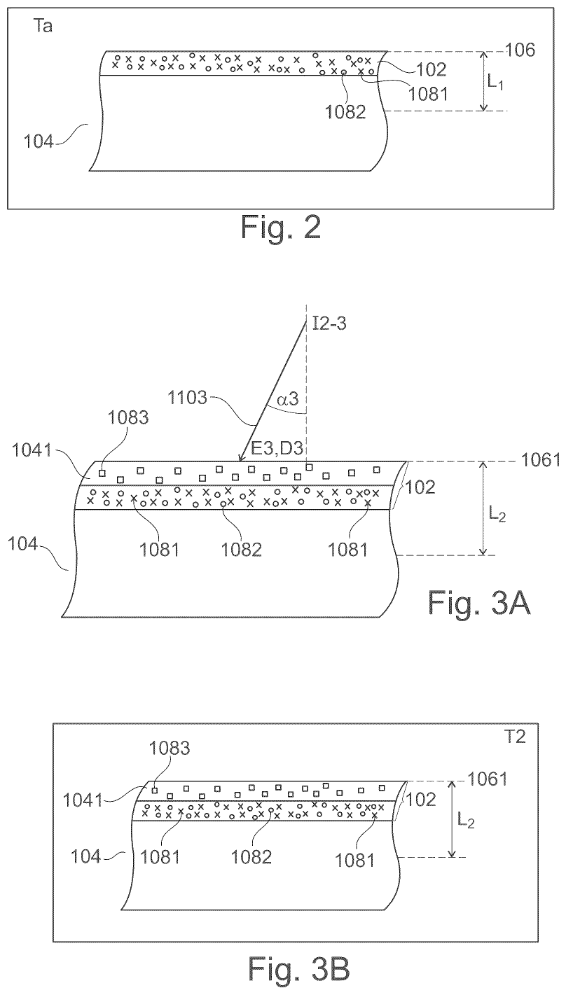

Referring to the schematic-cross sectional view of FIG. 2, the method for forming the doped region 102 may further include an activation heat treatment Ta applied to the semiconductor body 104 after the second ion implantation process I2-2. The activation heat treatment is configured to electrically activate the first and second dopants 1081, 1082.

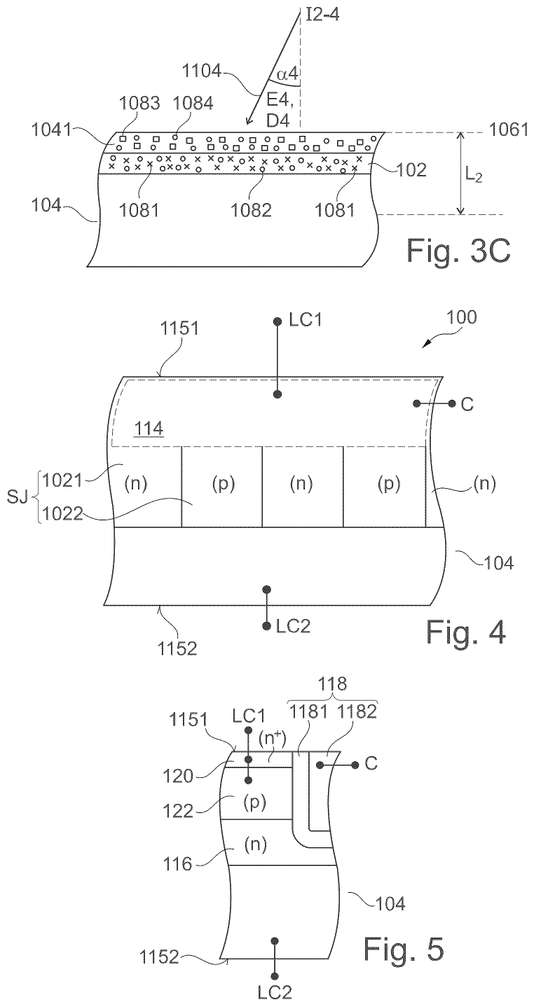

The method for forming the doped region 102 may include further process features described with reference to the schematic cross-sectional views of FIGS. 3A to 3C. The process features may be carried out after the process features illustrated in FIG. 1C and/or FIG. 2, or after the process features of FIG. 1C and before the process features of FIG. 2, for example.

Referring to FIG. 3A, forming the doped region 102 further includes forming a semiconductor layer 1041 on the first surface 106 of the semiconductor body 104. Third dopants 1083 are introduced through a surface 1061 of the semiconductor layer 1041 at a second vertical reference level L2 by a third ion implantation process I2-3. The third dopants 1083 are implanted along a beam axis 1103 having angle α3 with respect to the vertical axis on the surface 1061. For example, the angle α3 may deviate by at most 1.5° from a main crystal axis of the semiconductor body 104 along which channeling occurs, e.g. the c-axis in a SiC semiconductor body. The third ion implantation process I2-3 is based on an ion implantation energy E3 and an ion implantation dose D3.

Referring to FIG. 3B, forming the doped region 102 further includes applying a second heat treatment T2 to the semiconductor body 104 and the semiconductor layer 1041.

Referring to FIG. 3C, fourth dopants 1084 are introduced through the surface 1061 of the semiconductor layer 1041 at the second vertical reference level L2 by a fourth ion implantation process I2-4. The fourth dopants 1084 are implanted along the beam axis 1104 having angle α4 with respect to the vertical axis on the surface 1061. For example, the angle α4 may deviate by at most 1.5° from a main crystal axis of the semiconductor body 104 along which channeling occurs, e.g. the c-axis in a SiC semiconductor body. The fourth ion implantation process I2-4 is based on an ion implantation energy E4 and an ion implantation dose D4. An atomic number of the third dopants 1083 may be equal to an atomic number of the fourth dopants 1084. An ion implantation energy E4 of the fourth ion implantation process I2-4 differs by less than 20%, or by less than 10%, or by less than 5%, from an ion implantation energy E3 of the third ion implantation process I2-3. An ion implantation dose D4 of the fourth ion implantation process I2-4 differs by less than 20%, or by less than 10%, or by less than 5%, from an ion implantation dose D3 of the third ion implantation process I2-3.

In the example illustrated in FIGS. 1A to 1C in combination with FIGS. 3A to 3C, formation of the doped region 102 has been illustrated based on four ion implantation processes I2-1, I2-2, I2-3, I2-4. The four ion implantation processes for forming the doped region 102 are only exemplary and by no way limiting. Further ion implantation processes in addition to the first to fourth ion implantation processes I2-1, I2-2, I2-3, I2-4 may be carried out for forming the doped region 102. The ion implantation process(es) in addition to the ion implantation processes I2-1, I2-2, I2-3, I2-4 may be carried out before, between two of, or after the ion implantation processes I2-1, I2-2, I2-3, I2-4. For example, one or more semiconductor layers may be formed on the surface 1061 of the semiconductor layer 1041 and two or more additional ion implantation processes may be carried out to introduce dopants into each of the one or more semiconductor layers on the semiconductor layer 1041. This allows for a flexible design of a vertical doping concentration profile with respect to profile depth and profile shape, for example. Parameters of the additional ion implantation processes, e.g. ion implantation energy, and/or ion implantation dose, and/or ion implantation tilt angle with respect to the vertical axis may be similar to the first to fourth ion implantation process I2-1, I2-2, I2-3, I2-4, for example.

The schematic cross-sectional view of FIG. 4 illustrations a configuration example of a semiconductor device 100 that includes a super junction structure SJ comprising a p-doped region 1021 laterally adjoining an n-doped region 1022. The p-doped region 1021 and/or the n-doped region 1022 may be formed by the process examples described herein for forming the doped region 102. The semiconductor device 100 is schematically illustrated as a vertical power semiconductor device including a first load contact LC1, e.g. a source or emitter electrode, electrically coupled to a transistor cell area 114 via a first side 1151 of the semiconductor device 100. The transistor cell area 114 is illustrated in a simplified manner by a dashed box that may include any design of transistor cells, e.g. planar or trench gate designs. The super junction structure SJ is arranged between the transistor cell area 114 and a second side 1152 of the semiconductor device 100. A control electrode contact C, e.g. a gate pad, is electrically coupled to the transistor cell area via the first side 1051 of the semiconductor device 100. A second load contact LC2, e.g. a drain or collector electrode, is electrically coupled to the semiconductor body 104 via the second side 1152 of the semiconductor device 100.

The schematic cross-sectional view of FIG. 5 illustrations another example of a semiconductor device 100 configured as an n-channel trench gate MOSFET that includes an n-doped current spread region 116 adjoining to a trench gate structure 118 including a gate dielectric 1181 and a gate electrode 1182. The gate electrode 1182 is electrically connected to the control contact C. The first load contact LC1, e.g. a source contact, is electrically coupled to an n⁺-doped source region 120 and a p-doped body region 122 via the first side 1151 of the semiconductor device 100. The second load contact LC2, e.g. a drain electrode, is electrically coupled to the semiconductor body 104 via a second side 1152 of the semiconductor device 100.

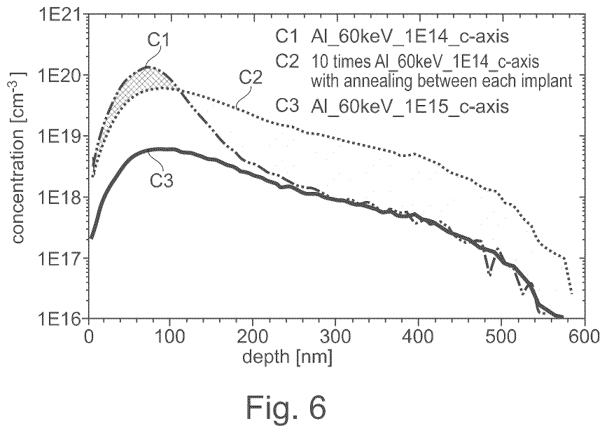

FIG. 6 is a schematic illustration of simulated channeling profiles of aluminum at 60 keV ion implantation energy into the c-axis of a SiC semiconductor body. Concentration profile C1 results from a high dose (1E15 cm⁻²) implantation and shows a distinct de-channeling peak at around 90 nm depth. Concentration profile C3 is based on the same simulation parameters as the concentration profile C1 but at a 10 times lower dose (i.e. 1E14 cm⁻²). Here, a more plateau-like profile is achieved. Concentration profile C2 is based on concentration profile C3 but multiplied by a factor of 10. Here it is assumed that the ion implantation at a dose of 1E14 cm⁻² is repeated 10 times and in between every implantation process an annealing of the crystal is carried out to retain the crystal structure and allow a constant channeling performance. The dashed area shows how much more aluminum concentration is present at larger depths and the checkered area shows how much concentration is reduced in the random depth compared to the concentration profile C1. The illustrated separation into ten consecutive implantation and annealing steps serves only for an illustrative purpose. How often the channeling implantation is to be divided into individual steps depends, for example, on the needs of the technology itself.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

Although specific embodiments have been illustrated and de-scribed herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device, the method comprising:
forming a doped region in a semiconductor body,
wherein forming the doped region includes:
introducing first dopants through a first surface of the semiconductor body at a first vertical reference level by a first ion implantation process;
after the introducing of the first dopants, applying a first heat treatment to the semiconductor body; and
after the applying of the first heat treatment, introducing second dopants through the first surface of the semiconductor body at the first vertical reference level by a second ion implantation process,
wherein an atomic number of the first dopants is equal to an atomic number of the second dopants,
wherein an ion implantation energy of the second ion implantation process differs by less than 20% from an ion implantation energy of the first ion implantation process,
wherein an ion implantation dose of the second ion implantation process differs by less than 20% from an ion implantation dose of the first ion implantation process.

2. The method of claim 1, wherein the second dopants are implanted along a beam axis that deviates by at most 1.5° from a main crystal axis of the semiconductor body along which channeling occurs.

3. The method of claim 1, wherein the first dopants are implanted along a beam axis that deviates by at most 1.5° from a main crystal axis of the semiconductor body along which channeling occurs.

4. A method of manufacturing a semiconductor device, the method comprising:
forming a doped region in a semiconductor body,
wherein forming the doped region includes:
introducing first dopants through a first surface of the semiconductor body at a first vertical reference level by a first ion implantation process, wherein the first dopants are implanted along a beam axis that deviates by at most 1.5° from a main crystal axis of the semiconductor body along which channeling occurs;
after the introducing of the first dopants, applying a first heat treatment to the semiconductor body; and
after the applying of the first heat treatment, introducing second dopants through the first surface of the semiconductor body at the first vertical reference level by a second ion implantation process, wherein the second dopants are implanted along a beam axis that deviates by at most 1.5° from the main crystal axis of the semiconductor body.

5. The method of claim 4, wherein the semiconductor body is a SiC semiconductor body and the main crystal axis is the c-axis.

6. The method of claim 4, wherein:
an atomic number of the first dopants is different to an atomic number of the second dopants; and/or
an ion implantation energy of the second ion implantation process differs by less than 20% from an ion implantation energy of the first ion implantation process; and/or
an ion implantation dose of the second ion implantation process differs by less than 20% from an ion implantation dose of the first ion implantation process.

7. The method of claim 4, wherein an ion implantation energy of the second ion implantation process is smaller than an ion implantation energy of the first ion implantation process.

8. The method of claim 4, wherein an ion implantation dose of the second ion implantation process is smaller than an ion implantation dose of the first ion implantation process.

9. The method of claim 4, wherein an ion implantation mask of the first ion implantation process is reused for the second ion implantation process.

10. The method of claim 4, further comprising:
after the second ion implantation process, applying an activation heat treatment to the semiconductor body,
wherein the activation heat treatment is configured to electrically activate the first and second dopants, and
wherein a maximum temperature of the activation heat treatment is larger than a maximum temperature of the first heat treatment.

11. The method of claim 10, wherein the maximum temperature of the activation heat treatment is larger by more than 400 K than the maximum temperature of the first heat treatment.

12. The method of claim 4, wherein a maximum temperature of the first heat treatment is configured to anneal crystal damage by the first ion implantation process.

13. The method of claim 4, wherein the semiconductor body is a SiC semiconductor body, and wherein a maximum temperature of the first heat treatment has a value from 600° C. to 1200° C.

14. The method of claim 4, further comprising ion implantation processes in addition to the first and second ion implantation processes, wherein each of the ion implantation processes in addition to the first and second ion implantation processes is carried out either before the first ion implantation process or after the second ion implantation process.

15. The method of claim 4, wherein the doped region is a p-doped region or an n-doped region of a super junction structure comprising the p-doped region laterally adjoining the n-doped region.

16. The method of claim 15, wherein the super junction structure is formed by:
forming a semiconductor layer on the first surface of the semiconductor body;
introducing third dopants through a surface of the semiconductor layer at a second vertical reference level by a third ion implantation process;
after the introducing of the third dopants, applying a second heat treatment to the semiconductor body and the semiconductor layer; and
after the applying of the second heat treatment, introducing fourth dopants through the surface of the semiconductor layer at the second vertical reference level by a fourth ion implantation process,
wherein an atomic number of the third dopants equals an atomic number of the fourth dopants, an ion implantation energy of the fourth ion implantation process differs by less than 20% from an ion implantation energy of the third ion implantation process, and an ion implantation dose of the fourth ion implantation process differs by less than 20% from an ion implantation dose of the third ion implantation process.

17. The method of claim 16, wherein:
both the first dopants and the second dopants form the n-doped region of the super junction structure; and
both the third dopants and the fourth dopants form the p-doped region of the super junction structure.

18. The method of claim 15, wherein the super junction structure is formed by:
forming a semiconductor layer on the first surface of the semiconductor body;
introducing third dopants through a surface of the semiconductor layer at a second vertical reference level by a third ion implantation process; and
introducing fourth dopants through the surface of the semiconductor layer at the second vertical reference level by a fourth ion implantation process,
wherein the introducing of both the first dopants and the third dopants is conducted prior to the first heat treatment, and
wherein the introducing of both the second dopants and the fourth dopants is conducted after the first heat treatment.

19. The method of claim 18, wherein:
both the first dopants and the second dopants form the n-doped region of the super junction structure; and
both the third dopants and the fourth dopants form the p-doped region of the super junction structure.

20. The method of claim 4, wherein the doped region is an n-doped current spread region of a power semiconductor device including gate trenches, the current spread region adjoining to a bottom side of the gate trenches.

21. The method of claim 4, wherein each one of an ion implantation energy of the first ion implantation process and an ion implantation energy of the second ion implantation process is larger than 1000 keV.

22. The method of claim 4, wherein a temperature of the semiconductor body during the introducing of the first dopants is smaller than the temperature of the semiconductor body during the introducing of second dopants.
